(19) United States
(12) Patent Application Publication
(10) Pub. No.: US 2002/0140053 A1
(43) Pub. Date: Oct. 3, 2002

(54) Thin-film resistor and method of fabrication

(76) Inventor: Jia-Sheng Lee, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/820,306

(22) Filed: Mar. 29, 2001

(51) Int. Cl. H01L 21/20; H01L 29/00

(52) U.S. Cl. 257/536; 438/382

(57) ABSTRACT

A thin-film resistor structure is disclosed. A resistor island is formed comprising of a resistor layer positioned on a dielectric layer, a protective layer laminated on the resistor layer, and a wet etch mask formed over the protective layer. Two dry-etched openings are fabricated in the wet etch mask, each over a respective end of the resistor layer. The two openings range vertically through the wet etch mask down to the surface of the underlying protective layer. Through the two openings, two self-aligned wet-etched vias are then formed within the protective layer, each atop a respective end of the resistor layer. The two self-aligned wet-etched vias are used to accommodate contact plugs.

### BACKGROUND OF THE INVENTION

1. Field of the Invention

The present invention relates to a thin-film resistor, and more particularly, to a clipped thin-film resistor for use on a semiconductor wafer and method of making the same.

2. Description of the Prior Art

Hitherto, many types of resistive components in the ICs of a semiconductor wafer have been developed, such as the gate conductive layers of semiconductor wafers, doped layers, and thin-film resistors. However, the main disadvantage of both the gate conductive layers and doped layers is their low resistance. To be of practical use, these components must therefore be manufactured at a large enough size to increase their resistance to a sufficient level; but, the nature of the small line widths of the gate conductive layers and the doped layers make them unsuitable for use in semiconductor processes. As well, in the presence of temperature change, the use of silicon as a conducting material in the gate conductive layers and doped layers produces variable conductivity in the resistive components, making their resistance unstable. Thus, in order to produce a resistive component of low conductivity and stable resistance, the use of a thin-film resistor is essential.

Please refer to FIG. 1. FIG. 1 is a schematic sectional diagram of a conventional thin-film resistor 20. A thin-film resistor 20 is positioned on a semiconductor wafer 10 and comprises a first dielectric layer 12, two conductive layers 14, a second dielectric layer 16, and a resistor layer 18. The first dielectric layer 12 is positioned on the surface of the semiconductor wafer 10. The two conductive layers 14 are positioned in a predetermined area of the first dielectric layer 12. The second dielectric layer 16 is positioned on the two conductive layers 14. Two separate openings are formed in the second dielectric layer 16 above the two conductive layers 14. The resistor layer 18 is positioned in a predetermined area of the second dielectric layer 16 and fills in the two openings above the two conductive layers 14. The ends of the two conductive layers 14 form separate contacts with the resistor layer 18, and are therefore used as electrical terminals of the resistor layer 18 when the semiconductor wafer 10 electrically connects with external components.

The first step in the formation of the thin-film resistor 10 involves positioning the two conductive layers 14 in the predetermined area on the first dielectric layer 12. The result is an uneven surface topography of the semiconductor wafer 10, leading to difficulty in step coverage of the following sequential deposition of the second dielectric layer 16 and the resistance layer 18 onto the semiconductor wafer 10. The varied thickness of the deposited resistance layer 18 can cause resistance difficulties. For instance, the two conductive layers 14 electrically link with the resistance layer 18 whereby greater resistance is generated in the thinner region of the resistance layer 18 while less resistance is generated in the thicker region of the resistance layer 18. Thus, a thin-film resistor with stable resistance is required as well as a method of fabrication that prevents plasma damage to the resistor.

### SUMMARY OF THE INVENTION

It is therefore a primary objective of the present invention to provide a thin-film resistor for use in a semiconductor wafer, and a method of its formation to solve the above-mentioned problems.

In a preferred embodiment, the present invention provides a thin-film resistor on a dielectric layer of a semiconductor wafer. A resistor island is formed comprising of a resistor layer positioned on the dielectric layer, a protective layer laminated on the resistor layer, and a wet etch mask formed over the protective layer. Two dry-etched openings are fabricated in the wet etch mask, each over a respective end of the resistor layer. The two dry-etched openings range vertically through the wet etch mask down to the surface of the underlying protective layer. From the two openings within the protective layer, two self-aligned wet-etched vias are then formed, each atop a respective end of the resistor layer. The two self-aligned wet-etched vias are used to accommodate contact plugs. Two metal wires, each positioned atop the respective end of the resistor layer, electrically connect with the resistor layer.

It is an advantage of the present invention that the thin-film resistor of the present invention has a stable resistance and can be used in processes requiring smaller line-widths, to reduce the overall area of the semiconductor product without sacrificing the critical dimension.

These and other objectives of the present invention will no doubt become obvious to those of ordinary skill in the art after having read the following detailed description of the preferred embodiment, which is illustrated in the various figures and drawings.

### BRIEF DESCRIPTION OF THE DRAWINGS

FIG. 1 is a sectional schematic diagram of the thin-film resistor employed in the semiconductor wafer according to the prior art.

FIG. 2 is sectional schematic diagram of the thin-film resistor employed in the semiconductor wafer according to the present invention.

FIG. 3 to FIG. 5 are schematic diagrams of the method for forming the thin-film resistor shown in FIG. 2.

FIG. 6 to FIG. 8 are schematic diagrams of an alternative embodiment according to the present invention.

### DETAILED DESCRIPTION OF THE PREFERRED EMBODIMENT

### Structure of the Thin-Film Resistor

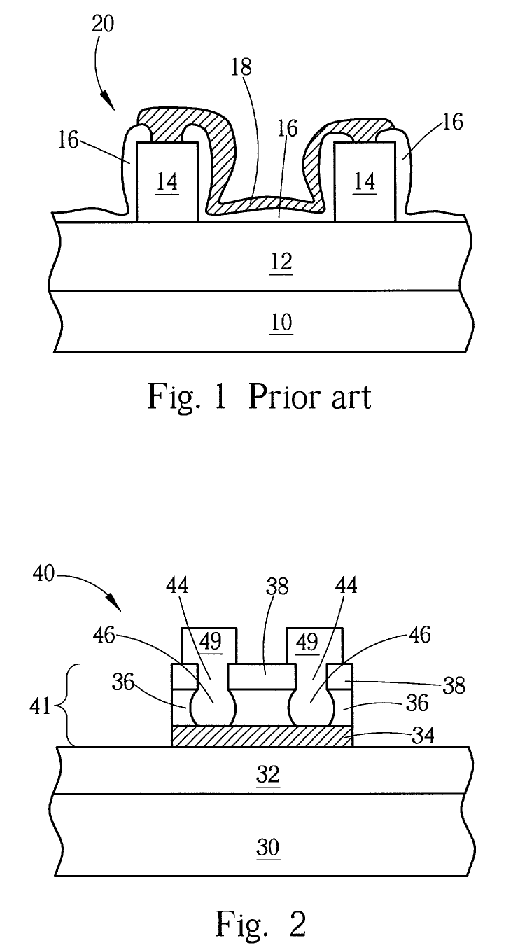

Please refer to FIG. 2 of a sectional schematic diagram of the thin-film resistor device 40 according to the present invention. A thin-film resistor device 40, positioned on a semiconductor wafer 30, comprises a dielectric layer 32 and a resistor island 41, respectively. The dielectric layer 32, formed of borophosphosilicate glass (BPSG) has a clean, planarized surface. The resistor island 41 consists of a resistor layer 34, a protective layer 36, and a wet etch mask 38, respectively. The protective layer 36, with a thickness of approximately 2000 angstroms, is formed of silicon nitride and is used to prevent plasma damage of the resistor layer 34. The resistor layer 34, formed of silicon chromium, has a thickness of approximately 500 to 1000 angstroms, preferably 700 angstroms. The wet etch mask is composed of materials, such as silicon oxide, not significantly affected by the phosphoric acid solution.

Two dry-etched openings 44 are fabricated in the wet etch mask 38, each over a respective end of the resistor layer 34. The two openings 44 range vertically through the wet etch mask 38 down to the surface of the underlying protective layer 36. Two self-aligned wet-etched vias 46 are formed within the protective layer 36, each atop a respective end of the resistor layer 34 and through each of the topenings 44. Each of the two self-aligned wet-etched vias 46, having an isotropic etched shape, is used for accommodating a contact plug.

The thin-film resistor device 40 further comprises a conductor (not shown in FIG. 2) filling the opening 44 and opening 46. The top end of the conductor protrudes from the upper surface of the wet etch mask 38, and the bottom end of the conductor connects one end of the resistor layer 34. The conductor functions as an electrical terminal of the resistor layer 34.

### Process of the Preferred Embodiment

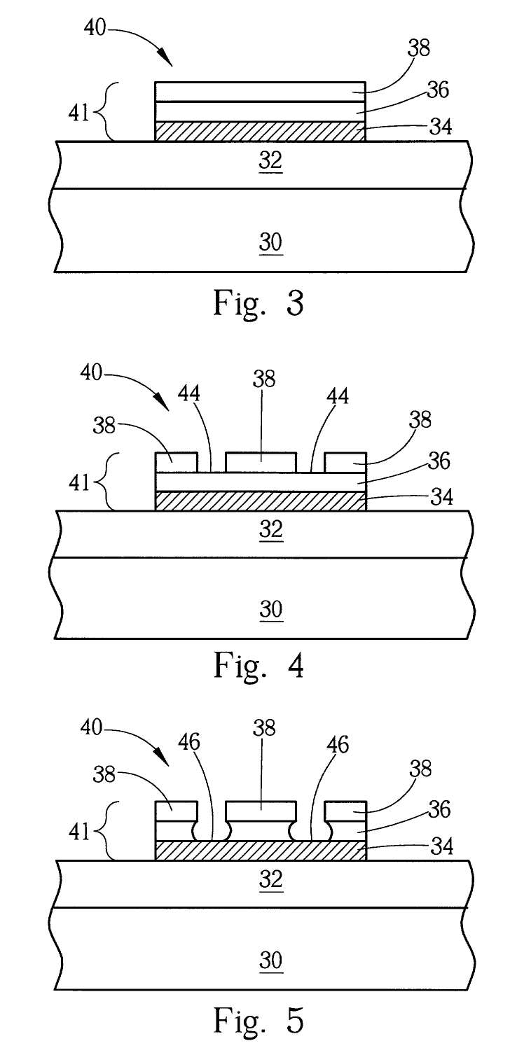

Please refer to FIG. 3 to FIG. 5. FIG. 3 to FIG. 5 are schematic diagrams of the method for forming the thin-film resistor device 40 shown in FIG. 2. The thin-film resistor device 40 is formed on the dielectric layer 32 positioned on the semiconductor wafer 30. The dielectric layer 32, preferably undergone a chemical mechanical polishing process, is first deposited over the semiconductor wafer 30. The dielectric layer 32 is made of borophosphosilicate glass (BPSG), phosphosilicate glass (PSG), or the like. A resistor layer 34 having a thickness of about 700 angstroms, a protective layer 36 having a thickness of about 2000 angstroms, and a wet etch mask layer 38 are subsequently formed over the dielectric layer 32, respectively. The resistor layer 34 is made of silicon chromium with silicon nitride as the preferred material for the protective layer 36 and silicon oxide as the preferred material for the wet etch mask 38. The protective layer 36 protects the resistor layer 34 from dry-etching-induced plasma damage. A conventional lithographic and an anisotropic dry-etching process are then performed to remove areas of the resistor layer 34, the protective layer 36 and the wet etch mask 38 outside a predetermined area to form a resistor island 41 on the dielectric layer 32.

As shown in FIG. 4, dry-etching is used to form the two openings 44 in the wet etch mask 38 and the process stops upon contact with the protective layer 34 to ensure the openings 44 extend down to the surface of the protective layer 34. As shown in FIG. 5, the protective layer 36 is then subjected to wet-etching with H₃PO₄ (phosphoric acid). The H₃PO₄ is introduced through the openings 44 to form the two wet-etched openings 46. Each opening 46 extends down, on opposite ends, to the surface of the resistor layer 34.

Finally, two separate conductive layers (not shown in FIG. 3 to FIG. 5) are formed in the two openings 44 and 46 whereby the conductive layers are made of aluminum alloy. The two conductive layers connect the two ends of the resistor layer 34. The top ends of the two conductive layers protrude from the upper surface of the wet etch mask 38 and function as electrical terminals of the ends of the resistor layer 34.

Due to the level surface of the dielectric layer 32, positioning the resistor layer 34 of the thin-film resistor device 40 on top does not lead to instability of resistor device 32 resistance when electrically connected. Also, during formation of the two openings 44 and 46 down to the resistor layer 34, dry-etching is first performed on the wet etch mask 38 followed by wet-etching on the protective layer 36. Therefore, the required surface area for the thin-film resistor device 40 is reduced and used in the production of a smaller gate width. Furthermore, formation of the two openings 44 down to the protective layer 36 prevents plasma damage to the resistor layer 34 and maintains stability of the resistance generated from the thin-film resistor device 40.

### Process of the Second Embodiment

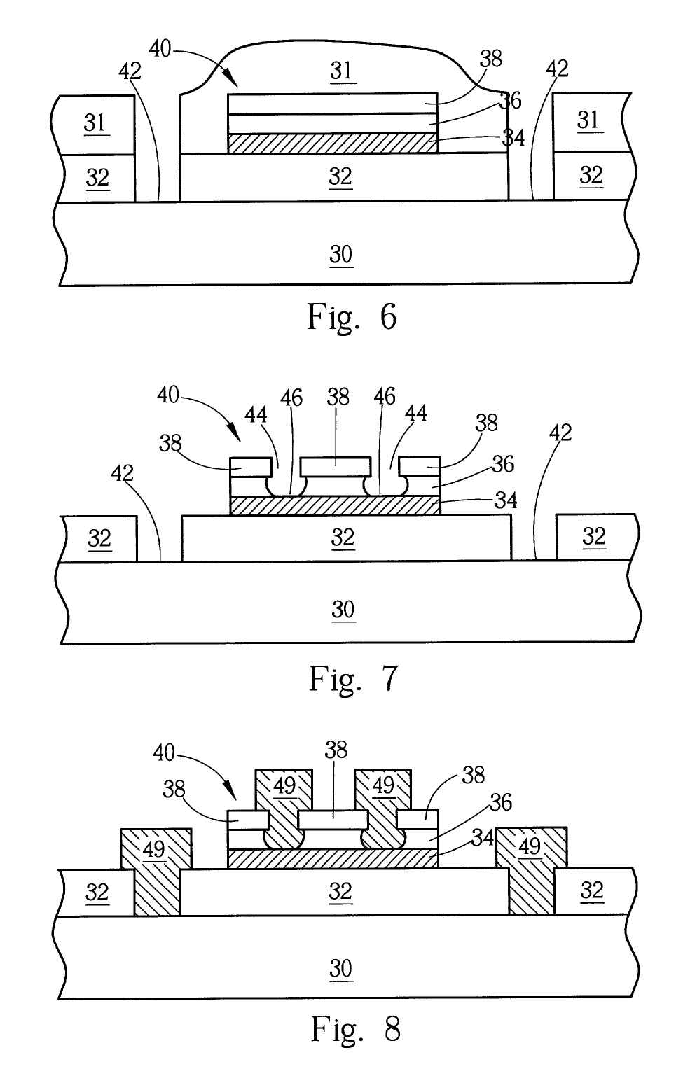

Please refer to FIG. 6 to FIG. 8. FIG. 6 to FIG. 8 are schematic diagrams of an alternative embodiment according to the present invention. According to the present invention, when the resistor layer 34, the protective layer 36 and the wet etch mask 38 have been formed in the predetermined area of the dielectric layer 32, dry-etching may be repeated in areas outside the predetermined area of the dielectric layer 32 to form two contact holes 42 as shown in FIG. 6. The two contact holes 42 function as channels of electrical connection between the devices of the semiconductor wafer 30. Then, both dry-etching and wet-etching are performed according to the aforementioned methods to form the two openings 44 and 46 down to the resistor layer 34 as shown in FIG. 7. Finally, the two separate conductive layers 49 are simultaneously formed in the two contact holes 42 and in the two openings 44 and 46 as shown in FIG. 8. Each conductive layer 49 is able to electrically connect to the device of the semiconductor wafer 30 through each contact hole 42.

In comparison with the thin-film resistor 20 of the prior art, the dielectric layer 32 of the present invention has a level surface to enable the formation of the resistor layer 34 of uniform thickness on the dielectric layer 32. As well, the two conductive layers 49 positioned in the two openings 44 and 46 extend down to the surface of the resistor layer 34 and connect the two ends of the resistor layer 34. Therefore, the resistance of the thin-film resistor device 40 remains stable.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A thin-film resistor comprising:
a dielectric layer formed over a semiconductor wafer;
a resistor layer formed in a predetermined area on the dielectric layer;
a wet etch mask layer formed above the resistor layer, comprising two dry-etched openings, each formed over a respective end of the resistor layer by a dry etching process; and
a protective layer, used to prevent plasma damage to the resistor layer interposed between the resistor layer and the wet etch mask layer from the dry-etching process, comprising two self-aligned wet-etched vias, each atop a respective end of the resistor layer;
wherein each of the two self-aligned wet-etched vias, formed through the two dry-etched openings, is used to accommodate a contact plug.

2. The thin-film resistor of claim 1 wherein the thickness of the resistor layer ranges from 500 angstroms to 1000 angstroms.

3. The thin-film resistor of claim 2 wherein the resistor layer is formed of silicon chromium.

4. The thin-film resistor of claim 1 wherein the protective layer is formed of silicon nitride with a thickness of about 2000 angstroms.

5. The thin-film resistor of claim 1 wherein the wet etch mask is formed of silicon oxide.

6. The thin-film resistor of claim 1 wherein the two self-aligned vias is formed by the use of a H₃PO₄ solution.

7. The thin-film resistor of claim 1 wherein the dielectric layer is formed of borophosphosilicate glass (BPSG).
